(19) United States
(12) Patent Application Publication
(10) Pub. No.: US 2010/0289035 A1
(43) Pub. Date: Nov. 18, 2010

(54) OPTOELECTRONIC DEVICE AND IMAGE RECORDING DEVICE

(75) Inventors: Julius Muschaweck, Gauting (DE); Ulrich Streppel, Furth (DE)

Correspondence Address: IP GROUP OF DLA PIPER LLP (US), ONE LIBERTY PLACE, 1650 MARKET ST, SUITE 4900, PHILADELPHIA, PA, 19103, US

(73) Assignee: OSRAM OPTO SEMICONDUCTORS GMBH, Regensburg (DE)

(21) Appl. No.: 12/808,206

(22) PCT Filed: Nov. 26, 2008
(86) PCT No.: PCT/DE08/01958

§ 371 Date: Jul. 30, 2010

(30) Foreign Application Priority Data
Dec. 21, 2007 (DE) 10 2007 062 038.3

(51) Int. Cl. H01L 31/12; H01L 33/58

(52) U.S. Cl. 257/84; 257/98; 257/E33.073; 257/E33.077

(57) ABSTRACT

An optoelectronic device includes an optical element and an optoelectronic semiconductor chip that generates electromagnetic radiation, wherein the optical element is of one-piece construction, includes two mutually facing radiation passage faces, comprises a lens arrangement with a plurality of mutually delimited lens regions, wherein the lens arrangement is formed in one of the radiation passage faces and the other radiation passage face is of smooth construction, and wherein the lens regions are arranged such that the radiation passing through the optical element is formed into different, cylindrical and/or mutually separate wavefronts.

### RELATED APPLICATIONS

This is a §371 of International Application No. PCT/DE2008/001958, with an international filing date of Nov. 26, 2008 (WO 2009/079971, published Jul. 2, 2009), which is based on German Patent Application No. 10 2007 062 038.3, filed Dec. 21, 2007, the subject matter of which is incorporated by reference.

### TECHNICAL FIELD

This disclosure relates to an optoelectronic device and an image recording device.

### BACKGROUND

It is desirable to generate regular patterns, for example, stripes on an object by means of a compact arrangement. Such patterns are necessary, for example, for autofocus sensors in digital cameras to produce a sharp camera image by recording the pattern and comparing it with setpoint geometries.

Such pattern generators have hitherto been produced by projection of a pattern in a similar manner to a slide projector.

When using an LED as light source, the contact structure on the surface of the LED chip may be imaged as the master pattern into the far field by means of a projection lens.

This means that:
a master pattern is provided, which is imaged, meaning in the case of slide projection an additional element in the structure,
there is a degree of dependency on the precision of the master pattern, which means that errors in the master pattern or production tolerances are imaged and lead to systematic deviations from the setpoint pattern geometry.

Pattern generation would additionally be possible by means of a free-form projection lens. However, calculation of the lens shape is extremely complicated, in particular, for extended sources. As a result of the complicated surface shape, the production of such lenses is comparatively complex.

### SUMMARY

We provide an optoelectronic device having an optical element and an optoelectronic semiconductor chip that generates electromagnetic radiation, wherein the optical element is of one-piece construction, includes two mutually facing radiation passage faces, includes a lens arrangement with a plurality of mutually delimited lens regions, wherein the lens arrangement is formed in one of the radiation passage faces and the other radiation passage face is of smooth construction, and wherein the lens regions are arranged such that the radiation passing through the optical element is formed into different, cylindrical and/or mutually separate wavefronts.

### BRIEF DESCRIPTION OF THE DRAWINGS

An optoelectronic device described here and an image recording device described here will be explained in greater detail below with reference to the drawings and with the aid of examples. Elements which are the same in the individual figures are indicated with the same reference numerals. The relationships between the elements are not shown to scale, however, but rather individual elements may be shown exaggeratedly large to assist in understanding.

FIG. 1 shows schematic side views of examples of optoelectronic devices described herein with a convex radiation entrance face (A) and a planar radiation exit face (B).

FIGS. 2 to 4 are schematic representations of further examples of optoelectronic devices described herein.

FIGS. 5 to 6 are schematic representations of further examples of lens regions described herein.

FIG. 7 shows schematic three-dimensional representations (A, C, E, G), and associated patterns (B, D, F, H) to be formed, of examples of optoelectronic devices described herein.

FIG. 8 is a schematic representation showing the dependency of an average diameter of the lens regions on a luminous flux of the semiconductor chip.

FIG. 9 is a schematic representation showing the dependency of the luminous flux of the semiconductor chip on a number of illumination islands.

FIG. 10 is a schematic representation of geometric relationships of the pattern to be formed.

FIG. 11 is a schematic representation of an example of an image recording device described herein.

### DETAILED DESCRIPTION

We found that an LED and a suitably shaped lens array may be combined together. If the initial starting point is in the middle of the LED chip, the spherical wavefront starting from this point is split or reshaped by the lens array into individual cylindrical wavefronts. Each of the cylindrical wavefronts then goes in a different direction and has a different angle of rotation of the cylinder axis. A point source in the middle of the LED thus becomes, for example, with appropriate arrangement of the lenses within the array, a perfect serrated discontinuous stripe pattern.

The individual lenses of the lens array (“lenslets”) are conveniently constructed such that imaging errors are corrected. This is made possible for the above-mentioned point source in the middle of the LED chip by suitable shaping of the lens surface. In addition, the front of the one-sided lens array may also be provided with a curvature and so reduce extra-axial imaging errors such as coma. Assumption of a point source thus gives rise to thin, sharp stripe patterns. If an extended source is used, as is the case in the LED, the stripes become correspondingly wider.

Further features and advantages which may be achieved within the context of our devices are:
No additional elements such as “master patterns” are necessary, the pattern being projected directly by the imaging optical system/lens array. The pattern may in particular simply be generated by the optical system. The structure is thereby made more compact.
Methods which are based on the slide projection principle, i.e., which illuminate a master pattern and then image it, are inefficient, since the majority of the luminous flux is lost during irradiation of the master pattern. It is here proposed, in contrast, to operate using the aperture division principle. The incoming wavefront is split into individual sub-wavefronts. No systematic shading then takes place.
Independence from source size and luminous flux of the light source: if the LED chip is made smaller, i.e., the emitted total luminous flux, the strips within the pattern become narrower but also brighter. Thus, the loss of total luminous flux is compensated. It is therefore possible to use small LED chips, i.e., chips with chip surface areas in the range from 200 μm×200 μm to 300 μm×300 μm.

The type of pattern generated is determined by the type of spatial arrangement of the lenslets. The lenslets may in this case be of different surface shapes and also different sizes. Different lenslet sizes enable adjustment of the brightnesses of the different stripes within the pattern.

A particular achievement lies in the combination of an LED and a suitably constructed lens array, i.e., one which has, for example, been corrected with regard to the imaging errors occurring in the arrangement, such that patterns may be generated in the far field without using a master pattern.

According to at least one example of our optoelectronic device, the latter comprises at least one optoelectronic semiconductor chip suitable for generating electromagnetic radiation. The semiconductor chip preferably takes the form of a light-emitting diode or a laser diode.

According to another example of the optoelectronic device, the latter comprises at least one optical element. The optical element is at least partially transmissive, in particular transparent, relative to the electromagnetic radiation generated by the optoelectronic semiconductor chip.

The optical element may be of one-piece construction. For example, the optical element may be formed using an injection molding or casting process. The optical element may be made from a glass or an epoxide. Preferably, however, the optical element consists of a plastics material, in particular, of a thermoplastic material, or of a silicone.

The optical element may comprise two radiation passage faces located opposite one another. The radiation passage face facing the optoelectronic semiconductor chip forms a radiation entrance face, while the radiation passage face remote from the semiconductor chip forms a radiation exit face. The radiation passage faces are in particular those faces of the optical element at which radiation undergoes refraction and/or which serve in purposeful beam shaping. In addition to the radiation passage faces, the optical element may comprise further faces, which serve, for example, in securing of the optical element.

The optical element may comprise at least one, in particular, exactly one, lens arrangement. In other words, lens-like configurations are fitted together in the optical element in a specific arrangement grid.

The lens arrangement may comprise a plurality of mutually delimited lens regions. Each lens region comprises a lens face, which forms a surface of the lens region and assumes a lens-like shape, in particular, a shape similar to a converging lens.

The lens arrangement may be formed in one of the radiation passage faces, in particular, in precisely one thereof. In other words, the lens faces of the lens regions form one of the radiation passage faces or at least a part thereof.

The radiation passage face in which no lens arrangement is formed may be of smooth construction. In this case, smooth means that this radiation passage face constitutes a single, continuous face. Preferably, the radiation passage face may, within the bounds of manufacturing tolerances, be described as a twice continuously differentiable face. Smooth, in particular, also means that the second derivative does not display any change of sign relative to the overall radiation passage face. In other words, this radiation passage face comprises at most one concave or at most one convex curvature profile. This radiation passage face is, in particular, not undulating in form.

The lens regions may be arranged such that the radiation passing through the optical element and, in particular, through various lens regions is shaped into different cylindrical and/or mutually separate wavefronts. In other words the lens arrangement comprises at least two lens regions, the radiation passing through these two lens regions, which is emitted by the optoelectronic semiconductor chip, being concentrated at least in part into different, mutually separated spatial regions. Separated spatial regions may mean that between these spatial regions, into which the radiation is concentrated, there are areas in which the intensity of the radiation is negligible, i.e., amounts, for example, to less than 15%, in particular, less than 3%, of the average intensity of the radiation in the spatial regions.

In at least one example of the optoelectronic device, the latter comprises an optical element and a semiconductor chip suitable for generating electromagnetic radiation. The optical element is of one-piece construction and contains two mutually facing radiation passage faces. The optical element additionally comprises a lens arrangement with a plurality of mutually delimited lens regions, wherein the lens arrangement is formed in one of the radiation passage faces and the other radiation passage face is of smooth construction. In addition, the lens regions are set up and arranged such that the radiation passing through the optical element is shaped by the respective lens regions into different, cylindrical and/or mutually separate wavefronts or pencils of rays.

The lens regions may be arranged such that, after passage of the radiation through the optical element, the wavefronts are configured by the lens regions such that they have different propagation directions and/or different angles of rotation relative to a cylinder axis. The cylinder axis is formed, in particular, by a center axis through the optoelectronic semiconductor chip. The cylinder axis is preferably oriented perpendicular to a radiation-emitting chip surface of the semiconductor chip. In other words, radiation emitted by the semiconductor chip, which passes through one of the lens regions, extends, after leaving the optoelectronic device, approximately in the form of a parallel pencil of rays and at a defined angle to the cylinder axis. Parallel here means that the divergence of the pencil of rays is not too great in at least one spatial direction, preferably in both spatial directions. Approximately parallel pencils of rays are thus generated by the lens regions of the lens arrangement which are emitted in particular, mutually different spatial directions. A divergence angle of the pencil of rays amounts to less than 10°, preferably less than 5°, in particular less than 2°.

The pencils of rays shaped by the individual lens regions may be convergent relative to at least one spatial direction. This means that the pencils of rays comprise a focal point or a focal line. The focal point or the focal line is located, in particular, at a distance of between 10 cm and 5 m, preferably between 50 cm and 2 m, from the radiation exit face of the device.

A distance between the semiconductor chip and the radiation entrance face, facing the semiconductor chip, of the optical element may amount to at least three times an average diameter of the semiconductor chip. If the semiconductor chip is square, for example, the average diameter corresponds to an edge length of the semiconductor chip.

The optical element may take the form of a supplementary element in front of the semiconductor chip. This means that the optical element with the semiconductor chip may be mounted on a common carrier or in a common mount. It is likewise possible for the optical element to be shaped in such a way that it may be plugged onto a support, on which the semiconductor chip is located, or placed over the semiconductor chip. It is not necessary for the optical element to be in direct contact with the semiconductor chip. For example, the semiconductor chip and the optical element do not touch one another.

The optical element may be integrated in the optoelectronic semiconductor chip. This may mean that the optical element is in direct contact with the semiconductor chip at least in places.

The lens arrangement may take the form of a lens array, in particular, the form of a flat lens array. In other words, a plurality of lens regions are arranged next to one another in a lateral direction.

The lens arrangement may be flat. In other words, the respective lens regions are located in a single plane. If the lens regions take the form of converging lenses, in particular, all the vertices of the individual lens regions are located in a single plane.

One of the radiation passage faces may be of planar construction. The radiation exit face, which is remote from the semiconductor chip, is preferably of planar construction.

At least two lens regions may have different shapes and different sizes, i.e., the lens regions extend, in particular, by different amounts along a radiation passage face of the optical element, on the side of which the lens arrangement is provided. Preferably, those lens regions which are formed further away from the cylinder axis have a larger surface area than those lens regions which are located closer to the cylinder axis.

The radiation emitted by the semiconductor chip may be imaged by means of passage through the optical element, in particular, through the lens arrangement, into a predetermined pattern. The pattern to be formed may be a two-dimensional grid and/or striped pattern.

An arrangement grid of the lens regions on the radiation passage face may correspond to a grid of a pattern to be formed or provided with the radiation. If, for example, the radiation is imaged in the form of pixels, the lens regions are likewise arranged in a cross-shaped grid.

The lens regions in each case may have precisely one refractive face, i.e., refraction takes place at precisely one boundary surface or transition between two different refractive indices. On passage through the optical element, precisely double refraction thus takes place, once at the radiation entrance face and once more at the radiation exit face.

The refractive faces of at least two lens regions may comprise different curvature profiles and different sizes. In other words, the lens arrangement cannot be produced by repeated copying or duplication of a single lens region.

The lens arrangement may comprise at least one, in particular, at least two, planes of symmetry in a direction perpendicular to the radiation passage face. If the lens arrangement is thus located on one side of the plane of symmetry, the lens arrangement is located on the other side of the plane of symmetry through reflection at the plane of symmetry. The cylinder axis is here, in particular, part of at least one plane of symmetry. The cylinder axis is preferably a line of intersection of the planes of symmetry.

Lens regions which are not intersected by the cylinder axis may comprise at most one plane of symmetry perpendicular to the radiation passage face. This at most one plane of symmetry preferably contains the cylinder axis.

The semiconductor chip may emit visible light or infrared radiation. The radiation is preferably spectrally narrowband and has wavelengths in the range between 580 nm and 1200 nm inclusive, in particular, between 620 nm and 850 nm inclusive. Spectrally narrowband here means that a spectral width, FWHM, of the radiation is less than 40 nm.

The lens regions may be corrected for imaging errors.

The latter may comprise precisely one semiconductor chip.

The latter may comprise precisely one optical element. The device preferably comprises precisely one semiconductor chip and precisely one optical element.

The latter may not have a negative mask or a positive mask for the pattern to be formed. This means, in particular, that there is no slide-type mask between the semiconductor chip and the optical element. Preferably the semiconductor chip and the chip surface does not have applied to it any texturing or pattern which is imaged and constitutes a pre-image for the pattern to be formed.

The latter may be provided for generating a preferably regular pattern on an imaging surface or on an object. The imaging surface is, in particular, at a distance from the light outlet face of between 0.1 m and 10 m inclusive, preferably between 0.2 m and 2 m inclusive.

The pattern to be formed may be an illuminance distribution pattern. In other words, the pattern is formed by defined intensity modulation of the radiation on the imaging surface.

The optical element may be configured and/or arranged in such a way that the pattern to be formed comprises a plurality of separate pattern regions, in particular, illumination islands. The pattern regions may likewise consist of individual, mutually separate stripes. The individual pattern regions are preferably of uniform size within the bounds of the manufacturing tolerances of the optical element. In the areas between the pattern regions, the intensity of the radiation is preferably negligible, as already described.

The optical element, in particular, the lens arrangement, may be arranged such that the radiation is shaped by the optical element, in particular, by the lens arrangement and the lens regions, in accordance with the pattern to be formed.

The semiconductor chip, in plan view onto the chip surface facing the optical element, may have an area of 400 μm×400 μm or less, preferably 300 μm×300 μm or less.

The semiconductor chip, in plan view onto the chip surface facing the optical element, may have an area of 150 μm×150 μm or more.

The radiant power emitted by each individual lens region may deviate from a mean, averaged over the radiation emitted by all the lens regions, by at most 25%. The lens arrangement is here preferably configured in the radiation exit face. In other words, each individual lens region emits a comparable radiant power.

An average diameter of the lens regions may amount to more than 1.5 times and less than 3 times an average diameter of the chip surface of the semiconductor chip facing the optical element. The size of the lens regions thus correlates with the size and/or with the luminous intensity of the semiconductor chip.

The latter may comprise a central lens region. The central lens region is intersected by the cylinder axis. The cylinder axis additionally constitutes an axis of rotational symmetry of the central lens region. In particular, the central lens region is spherical in shape.

At least one lens region, or refractive face thereof, may be aspherical in shape. Preferably all the lens regions are aspherically shaped, wherein the central lens region may be differently shaped. Aspherical means that the lens region is rotationally symmetrical but not spherical.

At least one lens region may be biconical in shape or configured as a toroidal lens or free-form lens. Preferably all the lens regions are shaped in this way, the central lens region possibly having a different shape.

The latter may be configured to generate a reference pattern for an autofocusing unit of an image recording device. In particular, the optoelectronic device serves to generate a reference pattern for an autofocus sensor. Such an autofocusing unit may, for example, be used in a camera, in particular, a digital camera, or in a mobile telephone or mobile computer with an image recording function.

This disclosure further relates to an image recording device. The image recording device comprises at least one optical device, as indicated in conjunction with at least one of the above-stated examples.

According to at least one example of the image recording device, the latter may comprise a sensor, which is set up to detect reflected radiation from the pencils of rays.

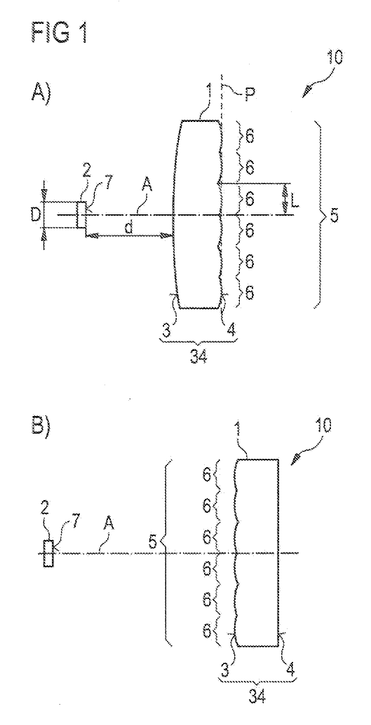

Turning now to the drawings, FIG. 1A shows an example of an optoelectronic device 10. An optoelectronic semiconductor chip 2 comprises a chip surface 7, facing an optical element 1. A cylinder axis A is arranged perpendicular to the chip surface 7 and intersects it centrally.

The optical element 1 comprises two radiation passage faces 34. The radiation passage face 34 facing the semiconductor chip 2 constitutes a radiation entrance face 3, while the radiation passage face 34 remote from the semiconductor chip 2 forms a radiation exit face 4. The radiation entrance face 3 is convexly curved. The radiation exit face 4 is divided into a plurality of mutually delimited lens regions 6. The lens regions 6 together form a lens arrangement 5. The lens arrangement 5 is thus formed in the radiation exit face 4. The individual lens regions 6 are in each case convex in shape, like a converging lens. All the vertices of the lens regions 6 are located, within the bounds of manufacturing tolerances, in a plane P. The vertices of the lens regions 6 should here be understood to be those points of the lens regions 6 which are furthest from the semiconductor chip 2 in a direction parallel to the cylinder axis A.

The convex radiation entrance face 3 is a smooth face, i.e., the radiation entrance face 3 is a single, continuous face. In addition, the radiation entrance face 3 comprises just one orientation of curvature. The radiation passage face 3 may, within the bounds of manufacturing tolerances, be described as a mathematical surface, comprising just one direction of curvature. If, in other words, this surface is twice derived, the second derivative does not display any change of sign.

A distance d between the semiconductor chip 2 and the optical element 1 amounts to at least three times the average diameter D of the semiconductor chip 2. If the semiconductor chip 2 is square, for example, the average diameter D corresponds to an edge length of the semiconductor chip 2. An average diameter L of the lens regions 6 is around twice the average diameter D of the semiconductor chip 2. Preferably, the average diameter L of the lens regions 6 is between 1.5 times and 3 times the average diameter D of the semiconductor chip 2.

FIG. 1B likewise shows a schematic side view of an example of the optoelectronic device 10. The lens arrangement 5 with the lens regions 6 is here formed in the radiation entrance face 3 and thus faces the optoelectronic semiconductor chip 2. The radiation exit face 4 is planar.

To simplify the illustration, the optical element 1 is arranged in a manner similar to FIG. 1A in the following examples. It is in each case equally possible for the optical element to be configured according to FIG. 1B, i.e., with the lens arrangement 5 facing the semiconductor chip 2.

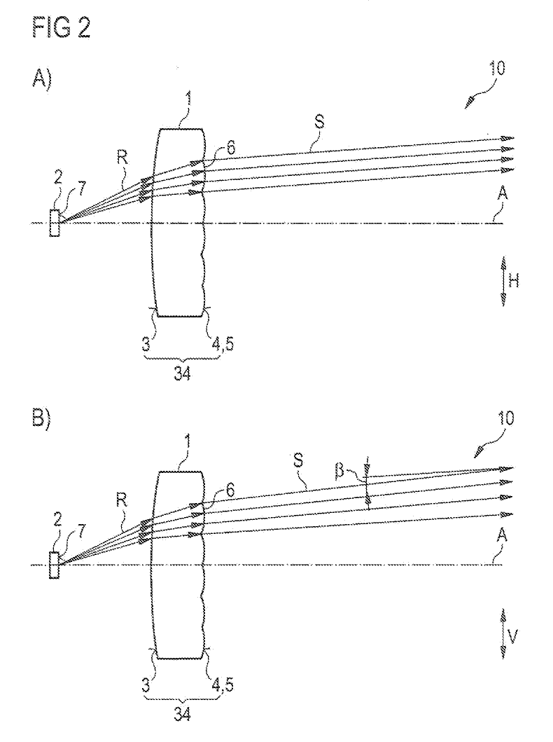

FIG. 2A shows a schematic plan view and FIG. 2B a schematic side view of a further example of the optoelectronic device 10. The course taken by radiation R emitted by the semiconductor chip 2 and by a pencil of rays S shaped therefrom by the optical element 1 are symbolized by arrow-headed lines.

The radiation R emitted by the semiconductor chip 2 at the chip surface 7 diverges in a direction towards the optical element 1. As a result of the convex shaping of the radiation entrance face 3 the radiation R is collimated. In other words, the divergence of the radiation R becomes less in the optical element 1. At the lens region 6, which takes the form of a convergent lens, further collimation takes place to yield the pencil of rays S. The pencil of rays S exhibits only negligible divergence in a horizontal direction H. In a vertical direction V, as in FIG. 2B, the pencil of rays S displays slight divergence, with a divergence angle β of around 2.5°. Shaping by the lens region 6 of the pencil of rays thus differs with regard to the horizontal direction H and vertical direction V.

FIG. 2 shows just the radiation R which impinges on a single, specific lens region 6. The mutually separate pencils of rays S shaped by each lens region 6 may in each case be guided in specific, different directions. This is illustrated schematically in FIGS. 3A and 3B by way of two examples of the optoelectronic device 10 with reference to two pencils of rays S1, S2. To simplify the illustration, the pencils of rays associated with the further lens regions are not shown. FIGS. 3A, 3B in each case show schematic plan views.

Radiation R1, R2 emitted in various directions by the semiconductor chip 2 passes via the radiation entrance face 3 into the optical element 1 and subsequently to different lens regions 6a, 6b. These lens regions 6a, 6b form different pencils of rays S1, S2, which constitute mutually separate, approximately cylindrical wavefronts. Cylindrical here means, in particular, that the pencils of rays S1, S2, projected onto a plane, result in a stripe pattern, and that the divergence of the pencils of rays S1, S2 is negligible. In the case of cylindrical wavefronts, the lens regions 6 are preferably similar in shape to cylindrical lenses and extend in a direction perpendicular to the cylinder axis A.

The pencils of rays S1, S2 have different angles of rotation a1, a2 relative to the cylinder axis A. According to FIG. 3A the angle of rotational amounts to around 5° and the angle of rotation a2 to around 13°. The lens arrangement 5 is preferably such that the pencils of rays comprise different angles of rotation, wherein the angle of rotation preferably also increases as the distance increases between the cylinder axis A and a lens region forming the pencil of rays. In other words, the individual pencils of rays of the radiation emitted or shaped by the individual lens regions 6 do not in this case intersect.

The examples according to FIGS. 3A and 3B differ in that according to FIG. 3A the radiation entrance face 3 is planar and according to FIG. 3B is convexly curved. The planar configuration of the radiation entrance face 3 may make it simpler to secure the optical element 1 to the semiconductor chip 2, for example, by means of a common support which is not shown. Convex curvature of the radiation entrance face 3 on the other hand simplifies the configuration of the individual lens regions 6, since the radiation R is collimated better by the radiation entrance face 3.

In contrast to FIGS. 2 and 3, the lens regions 6 may also be configured in such a way that the pencils of rays S1, S2 converge and form a focal point or a focal plane, for example, at a distance of around 1 m from the radiation exit face 4.

In the example according to FIG. 4, the various lens regions 6a, 6b, 6c comprise different average diameters La, Lb, Lc. The average diameters La, Lb, Lc increase away from the cylinder axis A. A plane of symmetry Y of the optical element 1 runs perpendicular to the plane of the drawing through the cylinder axis A. The optical element Y may also comprise a further plane of symmetry, for example, parallel to the plane of the drawing.

The radiation R1 impinges on the optical element 1 in a region which is further from the cylinder axis A than for the radiation R2. This makes the angle of incidence at which the radiation R1 impinges on the optical element 1 smaller than for the radiation R2. The different average diameters La, Lb, Lc ensure that, despite the different angles of incidence, each lens region 6a, 6b, 6c is supplied with comparable radiant power by the semiconductor chip 2. In this way, the pencils of rays S1, S2 have comparable luminous intensities.

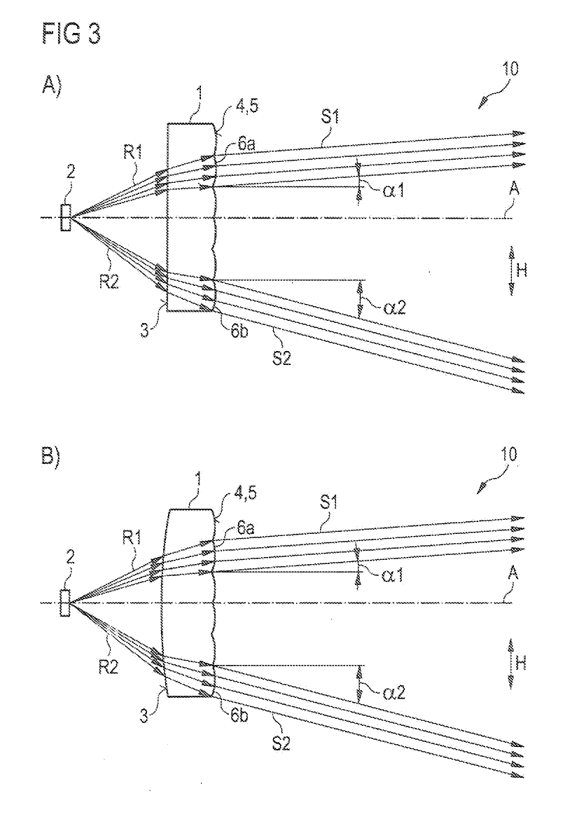

FIG. 5 shows the geometric parameters for a refractive surface or for the radiation passage face 35 of a lens region 6. A vertex of the lens region 6 lies at the origin of a z-r system of coordinates. The z axis forms the ordinate and is parallel to an optical axis of the lens region 6. The r axis orthogonal to the z axis, the r axis constituting the abscissa, substantially indicates the distance of a point from the z axis. The z axis thus constitutes, in particular, an axis of rotational symmetry, such that an r plane perpendicular to the z axis is defined by the r axis. At the vertex, the light passage face 34 exhibits lens curvature c, with c corresponding to the reciprocal of a radius of curvature at the vertex.

In the case of an aspherical radiation passage face 34, the shape thereof may be described using the following formula:

$$z ( r ) = \frac{c \cdot {r}^{2}}{1 + \sqrt{1 - ( 1 + k ) \cdot {c}^{2} \cdot {r}^{2}}} + {α}_{1} \cdot {r}^{2} + {α}_{2} \cdot {r}^{4} + … + {α}_{8} \cdot {r}^{16} .$$

z (r) here corresponds to a distance between a point on the radiation entrance face 34 and the r plane in a direction parallel to the z axis, this point being at a distance r from the z axis, in a direction perpendicular to the z axis.

k corresponds to the conicity while αᵢ are the aspherical coefficients. The parameter k has the effect that the lens profile is similar to a cone. In other words, the parameter k means that the distance between the r plane and a point on the radiation passage face 34 is smaller for large values of r than in the case of a spherical configuration of the lens region 6. By way of the aspherical coefficients, the configuration of the radiation passage face 34 may likewise be modified, in particular, in regions away from the z axis.

In the case of spherical shaping of the lens region 6, the radiation passage face 34 likewise complies with the above formula, the following applying for the parameters αᵢ and k: αᵢ=0, k=0.

The z axis is not necessarily an axis of rotation of the lens region 6. The lens region 6 may in such a case take the form of a toroidal lens or biconic lens. In this case, an x axis and a y axis orthogonal thereto define an xy plane, to which the z axis is perpendicular, corresponding to the r plane. The xy plane intersects the z axis at the vertex of the radiation passage face 34. The distance between a point on the radiation passage face 34 with the coordinates (x, y) and the xy plane may in this case be stated in particular using the following formula:

$$z ( x , y ) = \frac{{c}_{x} \cdot {x}^{2} + {c}_{y} \cdot {y}^{2}}{1 + \sqrt{1 - ( 1 + {k}_{x} ) \cdot {c}_{x}^{2} \cdot {x}^{2} - ( 1 + {k}_{y} ) \cdot {c}_{y}^{2} \cdot {y}^{2}}} .$$

Optionally, this formula may contain correction terms αᵢ·Eᵢ (x, y), in a similar manner to the formula for the configuration of an aspherical radiation passage face 34. The following applies here for Eᵢ: E₁=x, E₂=y, E₃=x², E₄=x·y, E₅=y², E₆=x³, E₇=x²·y, E₈=x·y², E₉=y³ and so on.

It is possible, moreover, for the shape of the radiation passage face 34 to comply with the formula neither for a spherical nor for an aspherical, nor for a biconic or toroidal lens. In this case, the lens is in particular a “free-form lens.”

FIG. 6 shows various examples of the lens regions 6 or the lens arrangement 5.

FIG. 6A shows a schematic side view of the lens arrangement 5. The lens region 6a comprises a vertex axis c2, which coincides with the cylinder axis A of the device 10. The lens region 6a with the average diameter L2 is rotationally symmetrical relative to the vertex axis c2.

The lens regions 6b, which have a larger average diameter L1 than the lens region 6a, are configured asymmetrically relative to the vertex axes c1 in the form of free-form lenses. All the vertex points of the lens regions 6a, 6b are located in the plane P. A depth t of the lens arrangement 5 is identical for all the lens regions 6a, 6b within the bounds of manufacturing tolerances.

FIGS. 6B and 6C show schematic plan views of a biconically configured lens region 6 and a lens region 6 configured as a free-form lens. The biconic lens region 6 according to FIG. 6B comprises two planes of symmetry Y1, Y2, which are oriented perpendicular to the plane of the drawing. The vertex axis c is formed by an axis of intersection of the planes of symmetry Y1, Y2. In the case of the lens region 6 of free-form configuration according to FIG. 6C, just one plane of symmetry Y is present. The vertex axis c is oriented perpendicular to the plane of the drawing, extends through the vertex and lies in the plane of symmetry Y. For example, the lens regions 6b are shaped as in FIG. 6A and in FIG. 6C. When the lens region 6 is configured as a free-form lens, it is likewise possible for the lens region 6 not to comprise a single plane of symmetry.

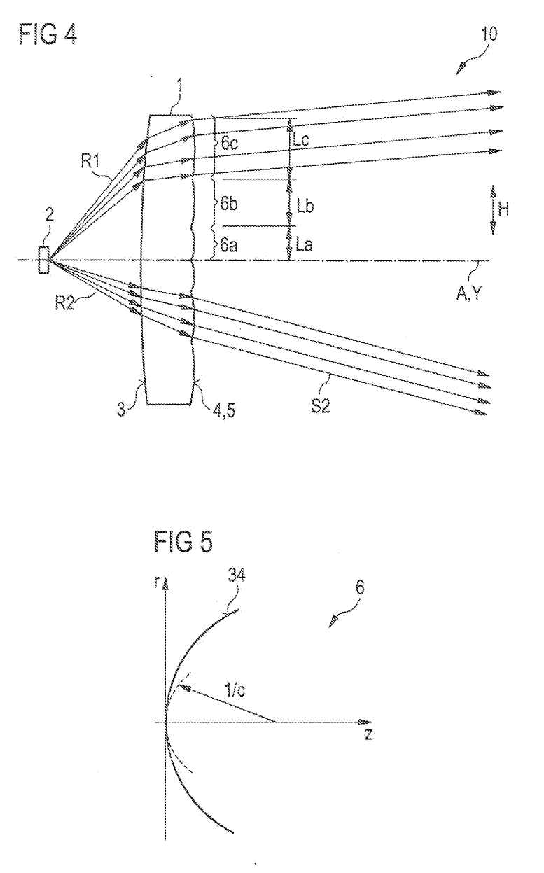

FIG. 7 shows a plurality of examples of the optoelectronic device 10. For a specific configuration of the optical element 1, in particular the lens arrangement 5 and the lens regions 6, a pattern 8 achieved and to be formed is shown in each case. The pattern 8 or the illuminance distribution thereof is given in each case at a distance of 1 m from the radiation exit face 4. The lens regions 6 are located for example at the radiation exit face 4, i.e., on the side of the optical element 1 remote from the optoelectronic semiconductor chip 2.

According to FIG. 7A, nine lens regions 6 are arranged in a square 3×3 grid. The associated pattern 8 to be formed, as in FIG. 7B, comprises nine illumination islands 9. The illumination islands 9 are separated from one another by dark areas and are arranged in accordance with the arrangement grid of the lens regions 6 on the radiation exit face 4. The illumination islands 9 are approximately square in shape. All the illumination islands 9 are of approximately equal brightness.

According to FIG. 7C, five inner lens regions 6a are arranged in a star shape. Four outer lens regions 6b are arranged at the corners of a square. The pattern 8 to be formed as shown in FIG. 7D again corresponds to the arrangement grid of the lens regions 6 and comprises the inner illumination islands 9a, 9c and the outer illumination islands 9b. With the exception of a central illumination island 9c, all the illumination islands 9a, 9b display comparable brightness. The central illumination island 9c appears brighter.

According to FIG. 7E, the lens regions 6 are arranged in a hexagonal pattern. The associated illumination islands 9, which are in each case separated from one another, likewise display a hexagonal pattern to be formed as shown in FIG. 7F.

According to FIG. 7G, eight further lens regions 6b are arranged in a ring about a central lens region 6c. The pattern 8 to be formed, as in FIG. 7H, corresponds to the arrangement pattern of the lens regions 6b, 6c. All the illumination islands 9 display comparable brightness.

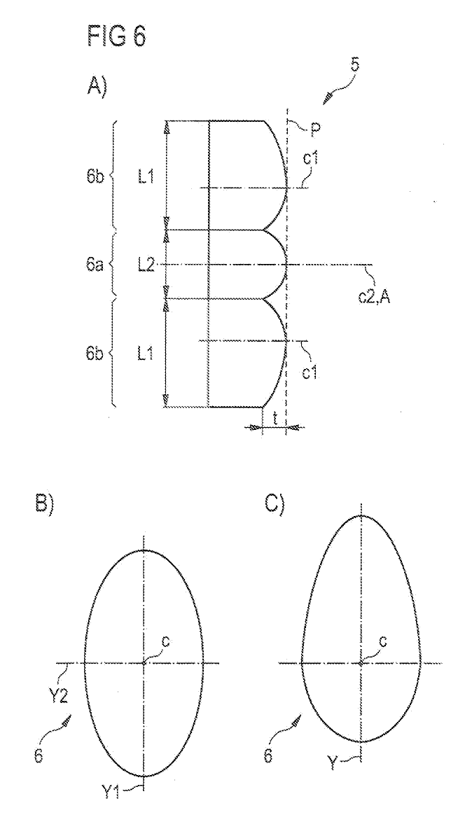

FIG. 8 states the average diameter L of the lens regions 6 in millimeters relative to a luminous flux Φ of the semiconductor chip 2 in lumens. The curves shown are related to different dimensions of the semiconductor chip 2. The luminous flux Φ of the light emitted by the semiconductor chip 2, under comparable operating conditions of the semiconductor chip 2, is in a simple approximation roughly proportional to the area of the semiconductor chip 2.

If the semiconductor chip 2, for example, comprises an area of 0.5×0.5 mm², cf. the rhombus curve, the average diameter L of the lens regions 6 varies in the range at around 1.4 mm for semiconductor chip 2 with a low luminous flux of around 30 lm. If the semiconductor chips 2 have an elevated luminous flux 4 of approximately 60 μm, the average diameter L amounts to around 1 mm. For all the curves shown, the average diameter L lies between 1.5 times and 3 times an edge length of the semiconductor chip 2. The illumination islands 9 here in each case display an illuminance of around 25 lm/m²=25 lx.

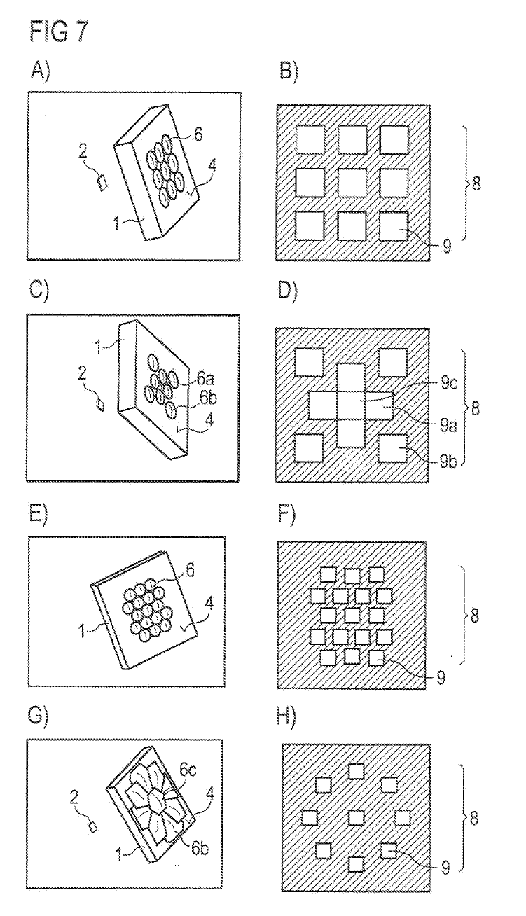

FIG. 9 shows the dependency of the necessary luminous flux Φ of the semiconductor chip 2 as a function of a number N of illumination islands 9. An illuminance E of an illumination island 9 results from the product of the luminous flux Φ of the semiconductor chip 2 times an efficiency s of the optical systems divided by the square of the number N of illumination islands 9 and divided by an area a of the illumination islands 9. If the optoelectronic device 10 is to be used in an autofocusing unit or in an autofocus sensor, an illuminance E of around 25 lx, equal to 25 lm/m², is required. The area a of the illumination islands 9 here amounts to around 3 mm², the distance between the optoelectronic device 10 and an object amounting to around 1 m. At such a distance, the area a of the illumination islands 9 preferably lies in the range between approx. 2 mm² and around 1 cm².

The efficiency s describes the efficiency of the optical element 1. The efficiency s is less than 1, since losses at the optical element 1 occur, for example, due to reflection at the radiation passage faces 34. Likewise, the radiation R emitted by the semiconductor chip 2 does not arrive in its entirely at the optical element 1. Since the semiconductor chip 2 corresponds only approximately to a point light source, losses likewise arise in optical imaging via the optical element 1. Efficiency s is typically in the range between 0.7 and 0.5.

On the basis of the interrelationship for illuminance E, the following interrelationship may be derived for the luminous flux Φ to be emitted by the semiconductor chip 2, with a given, required illuminance E and a given area a of the illumination islands 9, as a function of the number N of illumination islands 9 and as a function of the efficiency s:

$$Φ ( N ) = \frac{E \cdot a \cdot {N}^{2}}{s} .$$

For average efficiencies s of 0.6, luminous fluxes Φ of the semiconductor chip 2 in the range from 30 lm are sufficient for the pattern to be formed as illustrated, for example, in FIG. 7.

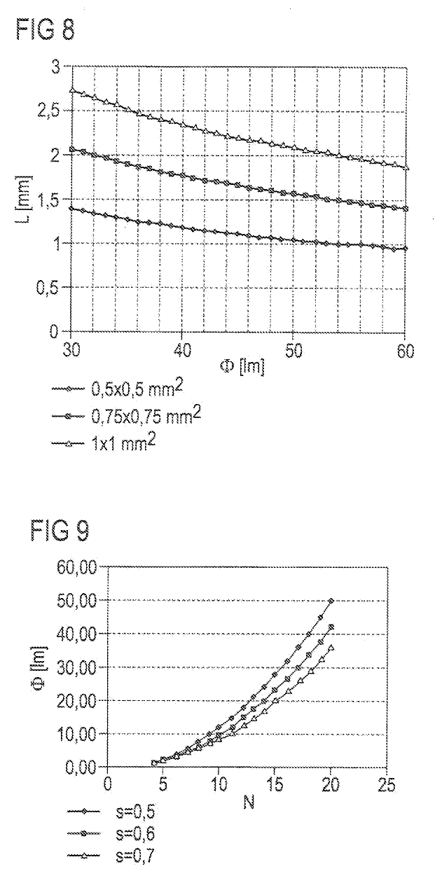

FIG. 10 is a schematic representation of a number of geometric parameters relating to formation of the pattern. The pattern 8 to be imaged is projected by the optoelectronic device 10 onto the object 11, for example, at a distance d of around 1 m. The object 11 is, for example, a type of screen or an item to be recorded by an image recording device. The pattern 8 is projected, relative to the cylinder axis A, in a region with an aperture angle γ of around 20°. The pattern 8 to be formed comprises a radius h of around 35 cm on the object 11.

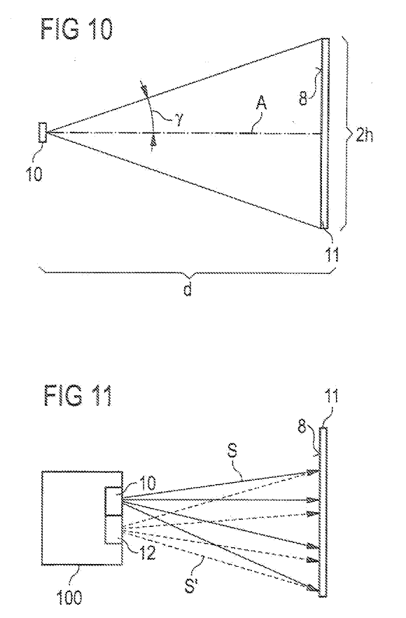

FIG. 11 is a schematic representation of an example of the image recording device 100. The pencils of rays S are projected onto the object 11 by the optoelectronic device 10. A pattern 8 to be formed according to FIG. 7, for example, or indeed a stripe pattern is formed by the device 10 on the object 11. A sensor 12 picks up radiation S′ from the pencils of rays S which is reflected diffusely by the object 11 and thereby determines a suitable focusing adjustment for the image recording device 100.

The devices described herein are not restricted by the description given with reference to the examples. Rather, the devices encompass any novel feature and any combination of features, including in particular any combination of features in the claims, even if this feature or this combination is not itself explicitly indicated in the claims or the examples.

1. An optoelectronic device having an optical element and an optoelectronic semiconductor chip that generates electromagnetic radiation, wherein the optical element
is of one-piece construction,
includes two mutually facing radiation passage faces,
comprises a lens arrangement with a plurality of mutually delimited lens regions,
wherein the lens arrangement is formed in one of the radiation passage faces and the other radiation passage face is of smooth construction, and
wherein the lens regions are arranged such that the radiation passing through the optical element is formed into different, cylindrical and/or mutually separate wavefronts.

2. The device according to claim 1, in which the lens regions are arranged such that, after passage of the radiation through the optical element, the wavefronts are configured such that they have different propagation directions and/or different angles of rotation relative to a cylinder axis.

3. The device according to claim 1, in which a distance between the semiconductor chip and the radiation passage face facing the semiconductor chip amounts to at least three times an average diameter of the semiconductor chip.

4. The device according to claim 1, in which the optical element takes the form of a supplementary element in front of the semiconductor chip.

5. The device according to claim 1, in which one radiation passage face is of planar construction.

6. The device according to claim 1, in which the lens regions have different shapes and different sizes.

7. The device according to claim 1, in which an arrangement grid of the lens regions corresponds to a grid of a pattern to be formed with the radiation.

8. The device according to any one of the preceding claim 1, in which the lens regions in each case have precisely one refractive face and the refractive faces of two lens regions have different curvature profiles and different sizes.

9. The device according to claim 1, which comprises one semiconductor chip and one optical element.

10. The device according to claim 1, which does not have a negative mask or a positive mask for a pattern to be formed.

11. The device according to claim 1, in which the semiconductor chip, in plan view onto the chip surface facing the optical element, has an area of more than 150 μm×150 μm and less than 400 μm×400 μm.

12. The device according to claim 1, in which radiant power emitted by each individual lens region deviates from a mean by at most 25%.

13. The device according to claim 1, in which an average diameter of the lens regions amounts to more than 1.5 times and less than three times an average diameter of a chip surface facing the optical element.

14. The device according to claim 1, which is configured to generate a reference pattern for an autofocusing unit of an image recording device.

15. An image recording device having an optical device according to claim 1 and a sensor which is set up for autofocusing.
